(19) United States
(12) Patent Application Publication
(10) Pub. No.: US 2009/0078202 A1
(43) Pub. Date: Mar. 26, 2009

(54) SUBSTRATE HEATER FOR MATERIAL DEPOSITION

(75) Inventors: Mikhail Strikovski, Rockville, MD (US); Solomon Kolagani, Ellicott City, MD (US); Jeonggoo Kim, Laurel, MD (US)

Correspondence Address: ROSENBERG, KLEIN & LEE, 3458 ELLICOTT CENTER DRIVE-SUITE 101, ELLICOTT CITY, MD, 21043, US

(73) Assignee: NEOCERA, LLC, BELTSVILLE, MD (US)

(21) Appl. No.: 11/861,717

(22) Filed: Sep. 26, 2007

(51) Int. Cl. C23C 14/54; A21B 2/00

(52) U.S. Cl. 118/725; 219/209; 392/416

(57) ABSTRACT

A radiative heater for substrates in a physical vapor deposition process for fabricating films of materials in a wide dynamic range of process temperatures and gas pressures includes a heat radiating member made from a high-temperature and oxidation resistant material tolerant to vacuum conditions which separates a heater volume containing heating filaments from a process volume which contains a deposition substrate heated by radiation of the walls of the heat radiating member. The heating elements extend through the body of the heat radiating member as well as in proximity to its surface to provide delivery of the heat to the substrate. The heat radiating member is shaped to form a cavity containing the substrate. The walls of the cavity envelope the substrate and radiate heat towards the substrate. Alternatively, the substrate is adhered to the flat surface of the heat radiating member.

### FIELD OF THE INVENTION

The present invention is directed to coating deposition; and in particular, to a substrate heater in a vapor deposition system.

More in particular, the present invention is directed to a substrate heater capable of uniformly heating substrates over a wide range of temperatures and is capable of operating under limitations of a multi-step deposition process.

### BACKGROUND OF THE INVENTION

In material deposition, specifically in coating deposition, a condensable material is provided in a process chamber which condenses onto a substrate so that the thickness of the coating increases with time. The condensable materials may be provided, at least in vicinity of the substrate surface, through variety of mechanisms. For example, a gas containing at least a fraction of the condensable matter, e.g., material's vapor, may serve as the condensation material source. The gas may also be supplied in a partially ionized (plasma) state. A condensable component may also be generated at the surface of the substrate. The essential requirement of the deposition process is that the condensable component remains on the surface of the substrate to permit the thickness growth of the deposited material during the process.

Delivery of a condensable material to a substrate may be accomplished through a Physical Vapor Deposition process in which a stream of atoms or ions, containing the material to be deposited is directed towards the substrate. The stream of particles is created by a source located in the process chamber or externally thereto. Kinetic energy of the particles, e.g., the energy range of the atoms or ions, may be within a wide range, from 1 eV to 100 keV. A particle stream of 1 eV to 300 eV energy can be generated, for example, via ablation of a solid tablet of the desirable material under impact of a powerful laser or electron beam. Such particles can condense on the substrate.

If the stream of particles contains a large amount of highly energetic particles (>300 eV), the coating formation starts from the accumulation of the particles under the substrate surface, e.g., the sub-plantation process, in which the initial accumulation is followed by coating of at yet a larger amount of the material delivered by the stream.

The coating properties dependent on temperature of the substrate, and on composition of the gas present in the process chamber. Frequently, a rather high temperature of several hundred ° C. is required at the substrate surface to facilitate formation of the coating with desired properties. The pressure and nature of a gas in the process chamber also affects the coating properties. These factors are especially important for complex, multi-component coating materials such as, for example, oxides and nitrides, which also may contain non-condensable elements. Incorporation of these elements, present in the process chamber in the gaseous state, in the coating process occurs via reaction on the surface. The reaction kinetics depends on the surface temperature and the process gas concentration. Optimal concentration of the gas may vary in a wide range, e.g., from a very low (vacuum) to atmospheric pressure (750 Torr).

Often the coating deposition process includes several steps with considerably different optimal temperature/pressure/gas requirements. For example the coating process sequence may include deposition of layers of several different materials, or annealing in the post-deposition processing. It is frequently required or desirable to perform the sequence within one “vacuum cycle”, that is without exposing the substrate to air or even without cooling it down between the layers deposition.

These conditions set significant limitations on the choice and design of a heater for heating the substrate up to the required temperature during each process step. A substrate heater desirably functions in specific narrow conditions of a single-step process, and also is to be able to provide heating in a wide variety of conditions for the multi-step deposition process. It is highly desirable to use a single heater for cooling/heating in all process steps. Operational conditions of such a “universal” heater must cover the gas pressure in the range from vacuum (<10⁻⁵ Torr) to 750 Torr and further be compatible with process gases, including oxygen and nitrogen. In addition to operating in the wide dynamic range of process parameters, the heater must meet such operational requirements as the process purity, heater lifetime, etc. Substrate heaters used in the industry, are generally able to operate only in a narrow range of specific conditions.

For heating a substrate to a temperature T, energy has to be transferred thereto by conduction, or radiation, or convection from an energy source (heater) whose surface temperature To>T. Transfer by convection is not applicable in most film deposition conditions, since density of particles in the chamber atmosphere is too small at a low pressure (<10 Torr) or vacuum conditions. Conduction of heat is effective only if a satisfactorily thermal contact can be established between the heater and the wafer. Often mechanical clamping does not produce good thermal contact, and then a soft, conformal to the heater and wafer surface material is used to fill the gap therebetween. Silver-loaded vacuum grease, or even soldering (with a low-temperature metal such as Indium, as example) may be used as the gap filler. This approach has a limited applicability however due to the facts that: (a) silver starts evaporating at temperature above ˜900° C., and contaminates the wafer surface; (b) wafers of a size greater than ˜20 mm may be damaged when removed from the heater after processing.

Heating by radiation is a convenient approach free from the drawbacks of conduction and convection. In radiation heating, the source of radiation is usually an electrically resistive hot wire (filament) heated by electrical current. For vacuum processing, Tungsten is an example of the suitable filament material as it is highly resistive, and has a high melting/evaporation temperature. The filament, however, cannot be used in a low vacuum, or in an oxidizing ambient gas in chamber since Tungsten oxidizes quickly and loses it's electrical conductivity.

Precious metals, like Platinum, do not oxidize even at a high temperature, and can be used as a radiative filament both in a vacuum and in oxygen processing. However, Platinum has very low emissivity, e.g., it radiates much less than a black material at the same temperature. Further, the platinum wire heater cannot be used as a contact heater. In addition, Platinum is prohibitively expensive for use in such applications.

Silicon Carbide (SiC) filament can be used in both vacuum and oxidizing process gas. The material, however, is known as producing contaminating particles in the process chamber, and therefore it cannot be used as a contact heater. In addition, maximum temperature of SiC stability in vacuum is limited to ˜1200° C. However, SiC is a suitable material for filaments to operate up to ˜1600° C. in oxygen.

Generally, it is beneficial to separate the volume containing filament and the process volume with a wall in order to protect filament from the process environment. Specifically, a metallic filament has to be protected from oxidizing environment, and SiC filament—fro vacuum environment.

To facilitate maximum radiation heat transfer from filament to substrate, it is generally desirable to have the wall to be transparent for the filament radiation.

To protect the filament from oxidation (if the filament is metallic, like Tungsten) it may be placed inside at least partially transparent envelope to provide different gas environments in the volume internal the envelope and the processing volume external the envelope. Tungsten-halogen radiant heaters have the envelope filled with a halogen gas. By using quartz as the enveloping material, maximum transparency for the filament radiation may be attained. These heaters have been widely used in the semiconductor industry for radiative heating of wafers during annealing. In contrast, in film deposition processes, the transparency requirement is a major drawback of these heaters. During deposition, some deposition material can unavoidably reach the envelope, deposit on the envelope, and may react with the envelope material. The envelope then loses its transparency, thus resulting in decrease in the wafer temperature, and an increase in the envelope temperature which leads to envelope failure. For this reason, the transparent envelope (separating wall) generally does not work well in film deposition.

Transparent envelope may be replaced in radiative heater designs with a metallic envelope, as it is found in Thermocoax heating coaxial cable, where the envelope is made from a high-temperature, oxidation-resistant material, for example Inconel. In this design, a ceramic powder isolates a hot filament wire from the envelope. The envelope outer surface serves as the surface for radiating energy to a wafer. Although this heater is tolerant to deposition of materials on the surface since it does not change the metal emissivity significantly. The cable-based heater, however, suffers from some drawbacks. First, the surface of the cable-made heaters is not flat, making the contact heating nearly impossible. Second, a chemical reaction between the hot filament material and the isolator material leads to failure of the filament. The reaction rate is higher at high temperatures which limits the operational temperature of the filament, as well as the maximum temperature of the radiating envelope, typically to 1000-1050° C.

A “universal” heater capable of providing the uniform heating of the substrate in a wide dynamic range of temperatures, pressure and process gases, which permits use in a multi-step coating process is a long-lasting need in the industry.

### SUMMARY OF THE INVENTION

It is therefore an object of the present invention to provide a “universal” substrate heater for a Physical Vapor Deposition process capable of wide dynamic ranges of operational parameters.

It is another object of the present invention to provide a substrate heater permitting uniform heating of a substrate to sufficiently high temperatures.

It is a further object of the present invention to provide a substrate heater usable for multi-layered vapor deposition.

The present substrate heater includes a heating assembly positioned in a heater volume and radiating heat to the substrate. The heating assembly includes a heat radiating member having walls defined between a heated surface and a radiating surface of the heat radiating member and an array of heating elements distributed in thermal communication with the heated surface of the heat radiating member. The substrate is positioned to be in thermal communication with the radiating surface.

The walls of the heat radiating member are shaped to form heater channels extending through the body of the heat radiating member. A portion of the heating surface of the heat radiating member defines a central cavity filled with a process media. The cavity accommodates the substrate therein. The heating elements are positioned in the heater channels as well as distributed over the heated surface of the heat radiating member, thereby providing a substantially uniform surrounding radiation towards the substrate.

Alternatively, the substrate may be glued to the radiating surface of the heat radiating member. It is preferred that the walls of the heat radiating member forming the heater channels, be curved to avoid mechanical stress and to reduce thermal loss.

The heat radiating member is shaped to conform with a shape of the substrate. For example, if the substrate is circularly shaped, then the walls of the heat radiating member are cylindrically contoured to form annularly shaped heater channels. If, however, the substrate is an elongated substrate, then heater channels extend substantially parallel each to the other along the sides of the substrate.

The walls of the heat radiating member separate the process volume filled with the process media from the heater volume. Preferably, side walls of the heat radiating member include heated wall portions exposed to heat radiation from the array of heating elements and unheated wall portions distant from the substrate.

An isolation element (member) is attached to the unheated wall portions of the side walls in order to thermally isolate the heated wall portions of the heat radiating member from an external area where an electrical contact array may be positioned. The isolation element also functions as a support for the electrical elements.

A thermoshield is positioned in enveloping relationship with the heat radiating member. The substrate may be supported by bottom walls of the thermoshield for rotational displacement. Alternatively, the substrate may be held by a shaft supported by the isolation element for rotational or linear displacement of the substrate within the heat radiating member.

Preferably shield plates are located between the isolation element and the heating elements to further improve the heat distribution in the system.

The heat radiating member may be formed from Inconel, while the heating elements may be formed from silicon carbide. A thermocouple (or another thermo-sensor) measures the temperature of the heat radiating member and communicates the data to an automatic temperature control loop which functions to control the temperature of the heat radiating member.

These and other features and advantages will become apparent after reading a further description of the preferred embodiment in conjunction with the accompanying patent drawings.

### BRIEF DESCRIPTION OF THE DRAWINGS

FIG. 1 is a schematic representation of operating principles of the present substrate heater in a vapor deposition apparatus;

FIG. 2 is a schematic representation of the present substrate heater;

FIG. 3 is a schematic representation of an alternative embodiment of the present substrate heater;

FIGS. 4A and 4B show a cross-section A-A of the substrate heater shown in FIGS. 2, 3 for a circular wafer (FIG. 4A) and a tape-like substrate (FIG. 4B); and

FIG. 5 is a schematic representation of another alternative embodiment of the present substrate heater.

### DETAILED DESCRIPTION OF THE PREFERRED EMBODIMENTS

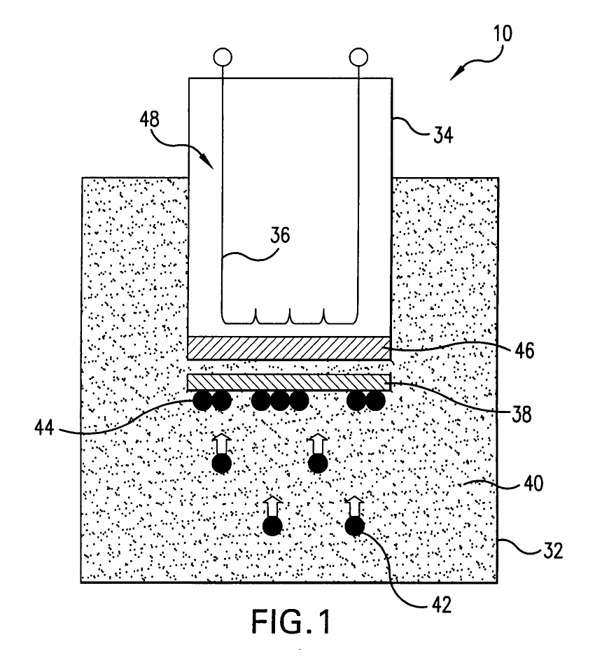

Referring to FIG. 1, illustrating the concept of the present substrate heater, a system 10 for material deposition includes a process chamber 32 and a heater chamber 34 separated each from the other by a high-temperature and oxidation resistant material which is tolerant to vacuum conditions. The heater chamber 34 contains a heating filament 36 and is filled with a gas suitable for the heating filament or it may be open to air.

A substrate 38 is positioned in the process chamber 32 which is filled with a process gas 40. The condensable particles (atoms/ions) 42 in the process chamber 32 flow to the substrate 38 and condense on the surface thereof to form a deposited material 44. The heat from the filament 36 is transferred to the substrate 38 through a hot (radiating) surface 46 formed from a high-temperature and oxidation resistant material, such as, for example, Inconel. By using the radiating surface 46, a uniform heating of the substrate 38 to high process temperatures may be attained.

The filament 36 and the radiating surface 46 constitute the substrate heater 48 of the present invention. The operational conditions of the heater 48 cover all or any combination of the following conditions:
Temperature of the hot surface 46 between 20 to 1150° C.
A flat shape of the hot surface exposed to the process volume 32
A flat-surface substrate can be directly attached to the heater surface
Capability to function in vacuum ambient (<10⁻⁵ Torr)
Capability to function at high pressure (up to 750 Torr) of process gas
Capability to function in the atmosphere of a process gas including oxygen or/and nitrogen
Capability to accept a directed stream of coating material
The heater surface does not produce contaminating particles in the process volume 32
Tolerance of the heater with respect to deposition of some material on surface 46
Filling the heater volume 34 with an optimal gas
Heater lifetime>5000 Hrs.

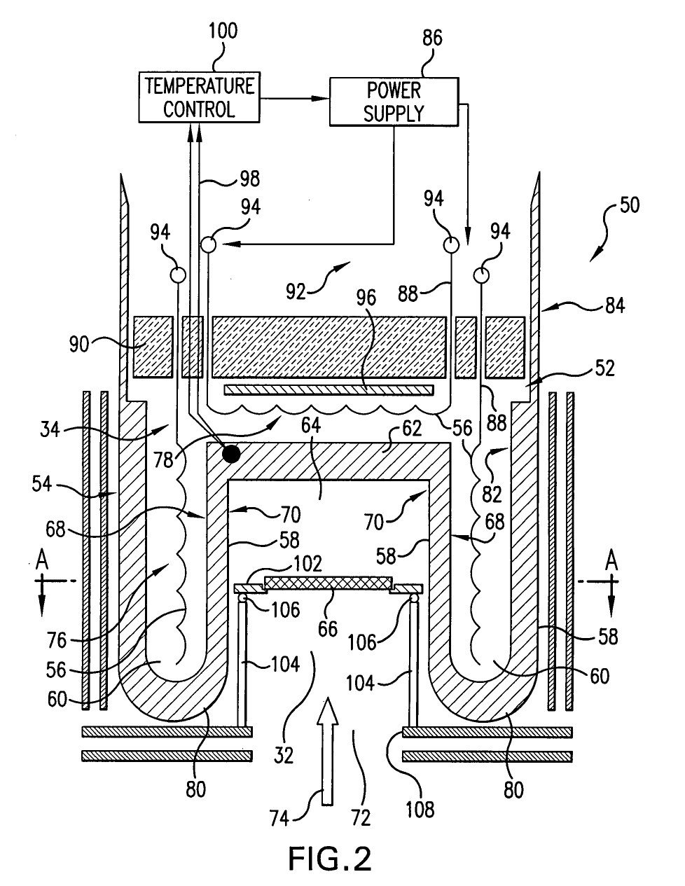

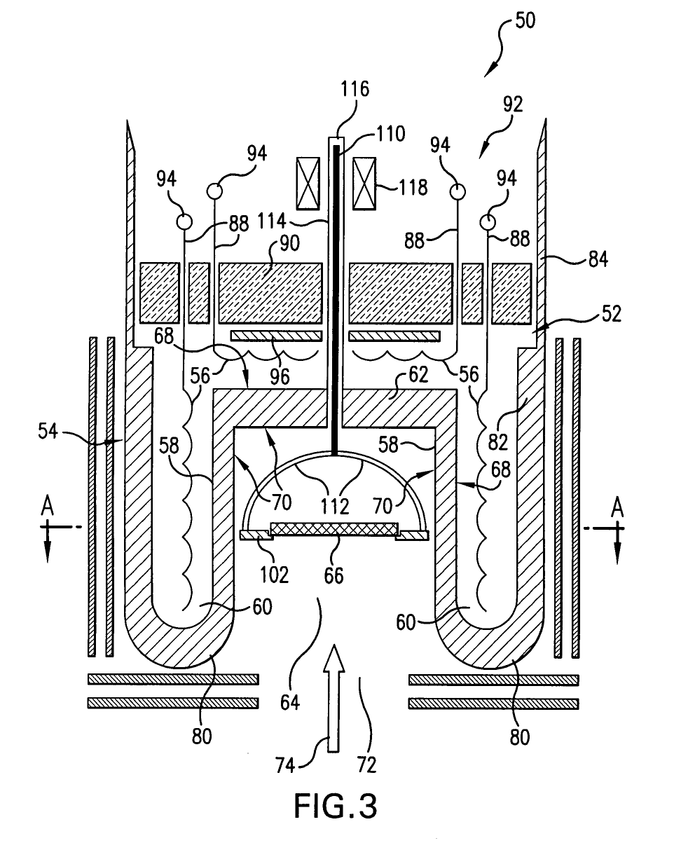

Referring to FIGS. 2-3, illustrating more in detail a cavity-like heater 50, the same includes a heating assembly 52 formed of a heat radiating member 54 and an array of heating elements 56. The heat radiating member 54 has side walls 58 shaped to form heat channels 60 and a bottom wall 62. The heat radiating member 54 is contoured specifically to form a cavity 64 defined by the side walls 58 and the bottom wall 62.

A substrate 66 is located inside the cavity 64 and thus is enveloped by the walls 58, 62 made of high-temperature, oxidation resistant metal. The walls 58, 62 have a heated surface 68 and a radiating surface 70. In this manner the substrate 66 receives the radiation from the hot radiating surface 70 of the walls 58, 62 except the opening 72 of the cavity 64. The opening 72 serves as an inlet port for the stream 74 of depositing material into the cavity 64.

The design of the present substrate heater 50 is intended to maximize the amount of the radiation received by the substrate as well as to minimize the amount of the radiation escaping. The radiation intensity Q depends strongly on the temperatures of the T radiating surface (as Q˜T⁴). Thus, increase of the maximal temperature of the walls 58, 62 of the heat radiating member which is of primary importance.

As can be seen in FIGS. 2-3, the heat radiating member 54 separates the heater volume 34 from the process volume (e.g., cavity 64). The heat radiating member 54 is at least partially, fabricated from Iconel© 600 (preferably, from Iconel 601). This material is chosen due to its stability in both vacuum and oxidizing environment up to 1200° C., and therefore may be used as the material separating the material deposition volume of the cavity 64 from the volume 34 containing the heating elements 56.

The heating elements 56 are arranged in sub-arrays including: (a) a sub-array 76 of the heating elements 56 which extend within the heater channels 60 defined between the side walls 58. It is important that the heater channels extend substantially through the entire “depth” of the heat radiating member 54 and that the heating elements 56 extend through the entire depth of the heater channels. It is also important, that the heating elements 56 are distributed uniformly along the length of the heater channels in order to provide uniform heating of the material of the side walls 68 and optimal conditions for the heat radiation from the heating surface 70 into the cavity 64; and (b) another sub-array 78 of the heating elements 56 is positioned in proximity to the heated surface 68 of the bottom wall 62. In this arrangement, the substrate 66 is enveloped by the radiating surface 70 which radiates heat thereto.

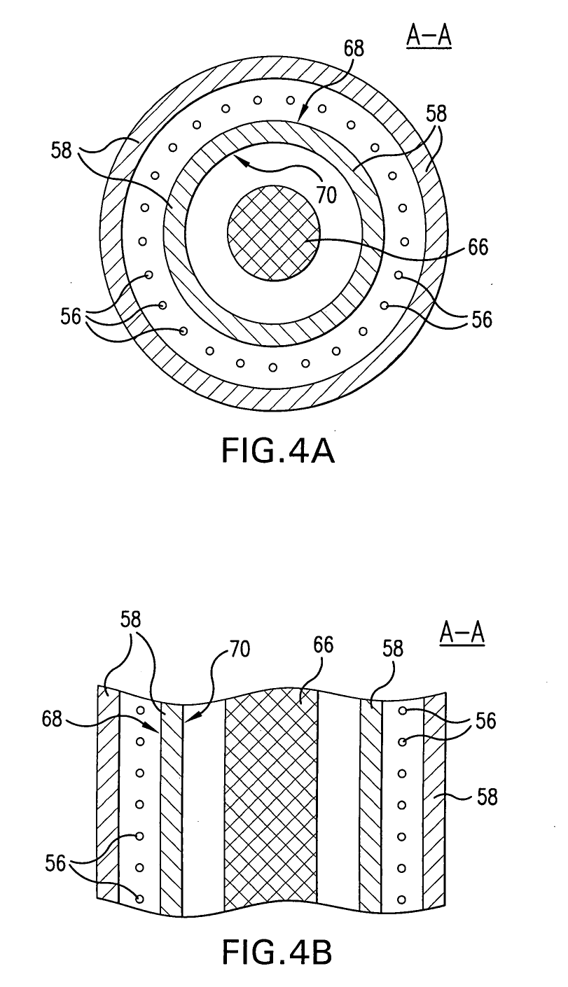

As shown in FIGS. 4A and 4B, presenting cross-section A-A of the arrangements shown in FIG. 2 or FIG. 3, the heat radiating member 54 is shaped in conformance with the substrate 66. As can be seen in FIG. 4A, if the wafer 66 is of a circular shape, then the heat radiating member 54 has cylindrically contoured side walls 58 which define annularly shaped heater channels 60 along which the heating elements 56 are circumferentially distributed.

If the substrate has an elongated tape-like shape, then the heat radiating member 54 is shaped accordingly. In this embodiment, the heater channels 60 extend in parallel each to the other along the substrate. The heating elements 56 are uniformly distributed along the parallel heater channels 60, as shown in FIG. 4B.

The heating elements 56 of the heater 50 may be fabricated, for example, from silicon carbide, SiC. The maximum temperature the SiC heating element can attain is ˜1550° C. when the element is in the air or at least in a partially oxidizing atmosphere. Air may be used as the ambient atmosphere in the heater volume 34, thereby facilitating the operation of the SiC heating elements 56 at their maximum temperature limited only by the SiC material intrinsic properties.

The radiation from the SiC element at 1550° C. could in principle heat up the Iconel walls 58, 60 to temperatures above 1200° C. However, there are two important factors that limit the usable temperature of Inconel for the application in vacuum film deposition process. The first factor is the gradual oxidation of the Inconel surface, accompanied by the oxidized layer flaking. This phenomena is observed at temperatures higher ˜1200° C. Flaking is not acceptable in film deposition. Another limitation is set by mechanical properties of Inconel. At high temperatures, and under pressure (force) load, the material softens and usually undergoes deformation. The heater may experience maximum mechanical load due to the outside atmospheric pressure when the process volume is at zero pressure (vacuum). The Inconel deformation rate increases quickly with temperature. At 1150° C. and under load of ˜170 PSI, the material deformation due to the changes in shape is ˜0.1% for 1000 Hrs of operation. This deformation level may be accepted for the operation of the substrate heater. Required material thickness to maintain the stress associated with the load of ˜170 PSI is also within reasonable limits. Thus, temperature of the walls in the heater is limited to 1150° C.

Thickness of the walls in the heat radiating member 54 has been optimized using simulation software for maintaining the mechanical stress below 170 PSI. An important feature of the embodiment is that there are no sharp angles created by the walls of the least radiating member. For example, rounded transitions 80 are formed between the cavity walls 58, as shown in FIGS. 2-3, to avoid the corner stress, thus permitting a reduction of the walls thickness and associated conduction heat losses.

The side walls 58 have a heated wall portion 82 and an unheated wall portion 84 which is not subjected to direct radiation of the SiC heating elements. The temperature of the unheated wall portion 84 is significantly lower than the temperature of the heated wall portion 82. The unheated wall portion 84 may sustain a significant stress, and it may have a reduced thickness of 2-3 mm thus further reducing conductive heat losses from the cavity 64. The heated wall portion 82 is thicker than the portion 84. For example, for the characteristic size S (diameter) of the cavity 64 (S≧25 mm), the thickness T of the heated wall portion 82 is approximately 2-3 mm<T<0.2 S. Preferably, the characteristic size of the cavity 64 is equal to the “depth” of the cavity.

The SiC heating elements 56 are located in the heater volume 34, and surround the cavity 64. At a heating element temperature of >700° C., the main channel of the heat transfer from the heating element to the cavity 64 is through radiation. For any given heating element temperature, the heating power density [W/cm₂] received by the cavity 64 is proportional to the radiating area of the heating element 56. In other words, not only the SiC heating element has to be at sufficiently high temperature, but also its design has to facilitate dense heating elements packaging. For this purpose, the heating elements in the present substrate heater are configured in such a way so as to maximize the radiating element area whereby the cavity 62 receives radiation from all sides except the open side of the cavity. In the embodiment shown in FIGS. 2, 3, the cavity of inner diameter of ˜25 mm can receive a power of up to 2000 W from the SiC heating elements 56. Each heating element 56 is connected to a power supply 86 through electrical leads 88 which are made thin enough to make conduction losses negligible.

An isolation member 90 is attached between the unheated walls portion 84 and the heated wall portion 82 of the side walls 58 to thermally isolate the heater volume 34 from the unheated wall portion 84 and a volume 92 in which contacts 94 for the electrical leads 88 are disposed. Another function of the isolation member 90 is to mechanically support the heating elements 56. The isolation member 90 is formed as a ceramic fiberboard, fabricated from SiO₂—Al₂O₃ based material able to work at temperatures up to ˜1800° C. At the same time it has very low thermal conductivity, which reduces conductive heat losses from the SiC heating elements 56.

At least one shield plate 96 is located between the SiC heating element 56 and the ceramic isolation member 90. The shield plate 96 intercepts radiation of the SiC heating element in the direction of the isolation member board 90, and thus is heated to further radiate a significant amount of radiation towards the cavity 62. The shield plate 96 thus increases efficiency of the substrate heater by attaining a higher cavity temperature at the same power of the SiC heating elements. The shield plate is formed of Inconel 601 foil. Several layers of similar shields 96 may surround the cavity 62. Front shields are formed with openings for deposition material access into the cavity 62.

A thermocouple 98 measures the temperature of the heat radiating member 54. The readout voltage of the thermocouple is used as a feedback signal for an automatic temperature control loop 100 in the heater power supply electronics 86. This mechanism does not constitute the inventive concept of the present invention and since it is known to those skilled in the art is not discussed herein in detail.

As shown in FIGS. 2 and 3, a substrate carrier 102 supports the substrate 60 at a pre-defined position in the cavity. The carrier 102 preferably has limited thickness in order to avoid (or limit) the “shadowing” of the substrate from the cavity walls radiation. Since the substrate thickness is small, the carrier having a thickness in the range of several mm would not make a significant difference in the amount of wall radiation received by the substrate laterally. The carrier 102 may be shaped as a disk or as a tape with a recessed central opening to receive the substrate.

In the embodiment shown in FIG. 2, the substrate carrier 102 is supported by stands 104 which are designed to cause a negligible “shadowing” of the substrate from the cavity wall radiation. For example, three rod-like stands of ˜3 mm diameter would obscure less than 5% of radiation of the lower section of the cavity 62. The stands 104 are preferably made from a low-thermal conductivity material, for example, quartz, and have a small cross-section to reduce conductive heat loss from the substrate carrier 102. To further reduce the conductive loss, the contact area between the substrate carrier 102 and the stand 104 is minimized by means of including a ball shaped spacer 106 between carrier 102 and stands 104. The spacer 106 has a negligible ring-like contact area with both the substrate carrier 102 and the stand 104.

A support member 108 supports the stands 104. At the same time, the support member 108 is one of the layers of the radiation shields 96. The support member 108 may be rotated to permit rotating of the substrate 66 for improved uniformity of the deposition.

An alternative design for the substrate support is shown in FIG. 3. A rotating shaft 110 passes through aligned openings in a cavity top (not shown), the isolation member 90 and the shield plate 96. The shaft 110, at least partially, is made from a low-thermal conductivity material, for example, quartz or porous alumina. Arctuated members 112 secure the substrate carrier 102 to the shaft 110. The members 112 have small cross-section to avoid the obscureness of the substrate to the cavity wall radiation. The shaft is enclosed in a vacuum tight envelope 114 which may be closed at its upper end by a cap 116. The shaft can rotate or translate laterally in z-direction to provide azimuthal and/or axial movement to the substrate. Rotation may be transferred to the shaft 114 magnetically through the envelope wall via a rotation/translation magnetic drive 118 and at least the upper part of the shaft length is magnetic. The substrate heater shown in FIG. 3 has the advantage of small size and does not necessitate rotation of large components such as the support member 108 in FIG. 2.

Numerical modeling of the heaters using RadTherm software shows that, in the substrate heater shown in FIG. 3, the wafer may be heated to the temperature of ˜1070° C. with the temperature of the walls in the range of 1150° C. Thus, the substrate temperature is approximately ˜80° C. lower than the cavity temperature in the cavity-like heater 50. The 1150° C. wall temperature may be attained with the SiC heating elements maintained at the temperature of 1500° C.

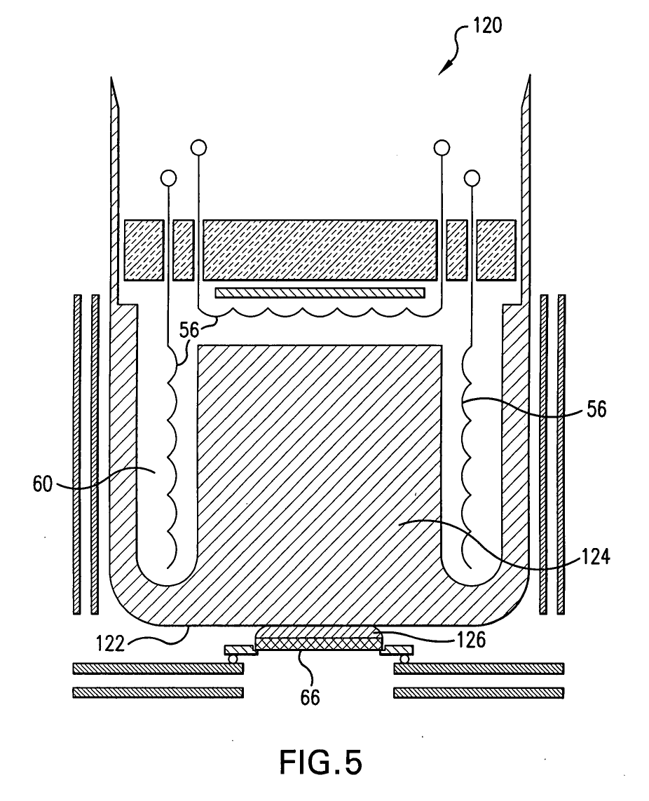

In the alternative embodiment shown in FIG. 5, the substrate heater 120 is “filled” with Inconel bulk material, and the substrate 66 is located in parallel (or in contact) to a flat surface 122 of the heater. The heater channels 60 extend through the bulk heater material 124. Heat transfer from the SiC heating elements 56 to the hot surface 122 is facilitated via conductance of the bulk heater material 124. The bulk material provides uniformity of the temperature over the area of the hot surface 122. The oxidized Inconel surface serves as the source of wide-spectrum radiation close to that of a black body. Temperatures of ˜950° C. was attained for the Si substrate located ˜3 mm apart from the hot surface 122 heated to a temperature of ˜1150° C. Although delivering a lower substrate temperature than in the cavity-like design presented in FIGS. 2, 3, the flat-plate open design shown in FIG. 5, however, permits the placing of the substrate 66 in close contact to the hot surface 122, or even adhering of the substrate thereto with a heat-conductive media/member 126 when needed.

Although this invention has been described in connection with specific forms and embodiments thereof, it will be appreciated that various modifications other than those discussed above may be resorted to without departing from the spirit or scope of the invention as defined in the appended claims. For example, equivalent elements may be substituted for those specifically shown and described, certain features may be used independently of other features, and in certain cases, particular applications of elements may be reversed or interposed, all without departing from the spirit or scope of the invention as defined in the appended claims.

What is claimed is:

1) A substrate heater for deposition of a coating material on a substrate, wherein the substrate is placed in a process volume filled with a process media, the substrate heater comprising:
a heater volume separated from the process volume, and
a heating assembly positioned in said heater volume and radiating heat to said substrate, said heating assembly including:
a heat radiating member having walls defined between a heated surface and a radiating surface of said heat radiating member, wherein said substrate is positioned in thermal communication with said radiating surface, said walls forming heater channels extending through said heat radiating member, and
a plurality of heating elements distributed in thermal communication with said heated surface of said heat radiating member, at least a portion of said plurality of the heating elements extending within said heater channels, thereby providing a surrounding heat radiation from said radiating surface of said heat radiating member to said substrate.

2) The substrate heater of claim 1, wherein said substrate is substantially circumferentially shaped, and wherein the walls of said heat radiating member are cylindrically contoured to form annularly shaped heater channels.

3) The substrate heater of claim 1, wherein said substrate is an elongated substrate, and wherein said heater channels extend substantially in parallel each to the other along said elongated substrate.

4) The substrate heater of claim 1, wherein at least a portion of said heating surface of said heat radiating member defines a central cavity, said central cavity being filled with the process media, said substrate being positioned in said central cavity.

5) The substrate heater of claim 1, wherein said walls of said heat radiating member separate said process volume filled with the process media from said heater volume.

6) The substrate heater of claim 4, wherein said walls of said heat radiating member include a heated wall portion exposed to heat radiation from said plurality of heating elements and an unheated wall portion distant from said substrate.

7) The substrate heater of claim 6, further comprising an isolation member attached between said unheated wall portion and said heated wall portion to thermally isolate said heated wall portion of said heat radiating member from an array of electrical contacts of said heating elements.

8) The substrate heater of claim 7, wherein said isolation member supports said array of the electrical contacts array.

9) The substrate heater of claim 1, further comprising a thermoshield enveloping said heat radiating member.

10) The substrate heater of claim 1, wherein said thermoshield includes bottom thermoshield walls and side thermoshield walls, said substrate being supported in position by said bottom thermoshield walls for rotational displacement.

11) The substrate heater of claim 7, further comprising a shaft supported by said isolation member and extending therethrough to support said substrate for rotational and linear displacement.

12) The substrate heater of claim 1, wherein said walls of said heat radiating member in said heater channels are curved to reduce mechanical stress and thermal loss.

13) The substrate heater of claim 7, further comprising at least one shield plate located between said isolation member and at least one of said heating elements.

14) The substrate heater of claim 1, wherein said heat radiating member is fabricated from Inconel.

15) The substrate heater of claim 1, wherein said heating elements are fabricated from silicon carbide.

16) The substrate heater of claim 6, wherein said central cavity has a predetermined diameter S, wherein the thickness T of said heated wall portion falls in the range of 2-3 mm<T<0.25 mm, and wherein the thickness of the unheated wall portion falls in the range of 2-3 mm.

17) The substrate heater of claim 7, wherein said isolation element is fabricated from SiO₂—Al₂O₃ based material.

18) The substrate heater of claim 1, further comprising a thermosensor for measuring the temperature of said heat radiating member, a power supply, and an automatic temperature control loop receiving said temperature from said thermosensor and adjusting said power supply parameters to control the temperature of said heat radiating member.

19) The substrate heater of claim 1, wherein said substrate is secured in proximal contact with said radiating surface of said heat radiating member.

20) A substrate heater for deposition of a coating material on a substrate, comprising:
a heating assembly positioned in a heater volume, said heating assembly including:
a heat radiating member having walls defining a cavity therebetween and enveloping a substrate positioned in said cavity, said heat radiating member separating the heater volume from a process volume, said walls having a heated surface exposed to said heater volume and a radiating surface exposed to said process volume,
wherein the substrate is positioned in said cavity in thermal communication with said radiating surface of said walls of said heat radiating member, and wherein said walls form heater channels extending through said heat radiating member, and
a plurality of heating elements distributed in thermal communication with substantially the entire said heated surface of said heat radiating member, at least a portion of said plurality of the heating elements extending within said heater channels.
